(19) United States
(12) Patent Application Publication
(10) Pub. No.: US 2013/0200389 A1
(43) Pub. Date: Aug. 8, 2013

(54) NITRIDE BASED HETEROJUNCTION SEMICONDUCTOR DEVICE AND MANUFACTURING METHOD THEREOF

(71) Applicant: SAMSUNG ELECTRONICS CO., LTD., Gyeonggi-do (KR)

(72) Inventor: Jae Hoon Lee, Gyeonggi-do (KR)

(73) Assignee: SAMSUNG ELECTRONICS CO., LTD., Gyeonggi-do (KR)

(21) Appl. No.: 13/759,944

(22) Filed: Feb. 5, 2013

(30) Foreign Application Priority Data
Feb. 6, 2012 (KR) 10-2012-0011891

(51) Int. Cl. H01L 29/205

(52) U.S. Cl. CPC H01L 29/205
USPC 257/76; 438/285

(57) ABSTRACT

A nitride based heterojunction semiconductor device includes a gallium nitride (GaN) layer disposed on a substrate, an aluminum (Al)-doped GaN layer disposed on the GaN layer, an AlGaN layer disposed on the Al-doped GaN layer, an ion-implanted layer disposed in an area on the AlGaN layer, excluding a first area and a second area.

### CROSS-REFERENCE TO RELATED APPLICATION

This application claims benefit of priority to Korean Patent Application No. 10-2012-0011891, filed on Feb. 6, 2012, in the Korean Intellectual Property Office, the entire contents of which are hereby incorporated by reference.

### TECHNICAL FIELD

The present inventive concept relates to a nitride based heterojunction semiconductor device and manufacturing method thereof that may reduce a leakage current by stabilizing a surface state of a device.

### BACKGROUND

With rapid development of information and communications industry, a demand for wireless communication technologies, for example, personal mobile communication, wideband communication, military radar, and the like, is gradually rising. Accordingly, there is an increasing need for a high output and high frequency device with a high level of information processing technology. A gallium nitride (GaN) material that can be used for a power amplifier may be suitable for the high output and high frequency device since the GaN material has properties of a relative great energy band gap, a relatively high heat conductivity, and the like, when compared to conventionally used materials such as a silicon (Si) material and a gallium arsenide (GaAS) material.

A semiconductor device, for example, an AlGaN/GaN heterojunction field effect transistor, may have a high band discontinuity at a junction interface, and a high-density of electrons may be freed in the interface. Thus, an electron mobility may increase. However, since the AlGaN/GaN heterojunction field effect transistor may have an unstable surface state of an AlGaN layer, a leakage current may occur on the surface of the AlGaN layer. Therefore, an issue exists in that the leakage current may cause a decrease in a reliability of a semiconductor device.

### SUMMARY

An aspect of the present inventive concept relates to a nitride based heterojunction semiconductor device and manufacturing method thereof that may reduce a leakage current on a surface of an aluminum gallium nitride (AlGaN), by forming an ion-implanted layer on the surface of AlGaN layer.

An aspect of the present inventive concept encompasses a nitride based heterojunction semiconductor device, including a GaN layer disposed on a substrate, an Al-doped GaN layer disposed on the GaN layer, an AlGaN layer disposed on the Al-doped GaN layer, and an ion-implanted layer disposed in an area on the AlGaN layer, excluding a first area and a second area.

The ion-implanted layer may be formed by implanting at least one ion of argon (Ar), carbon (C), hydrogen (H), and nitrogen (N).

The semiconductor device may further include a passivation layer disposed on the ion-implanted layer.

The semiconductor device may further include a Schottky electrode disposed in the first area, and an ohmic electrode disposed in the second area.

The ion-implanted layer may be disposed in an area on the AlGaN layer, excluding a third area that is separate from the first area and the second area,.

The semiconductor device may further include a source electrode disposed in the first area, a gate insulating layer disposed in the second area, a gate electrode disposed on the gate insulating layer, and a drain electrode disposed in the third area.

The AlGaN layer may has an etched area in which the Al-doped GaN layer is exposed through the second area.

The gate insulating layer may be disposed between the etched area and the gate electrode.

A portion of the ion-implanted layer may be disposed between the first area and the second area on the AlGaN layer.

Another aspect of the present inventive concept relates to a method of manufacturing a nitride based heterojunction semiconductor device. The method includes forming a GaN layer, an Al-doped GaN layer, and an AlGaN layer on a substrate, sequentially. An ion-implantation preventing film is formed in a first area and a second area on the AlGaN layer. An ion-implanted layer is formed by implanting an ion on the AlGaN layer. The ion-implantation preventing film is removed to expose the AlGaN layer through the first area and the second area.

In the forming of the ion-implanted layer, at least one ion of Ar, C, H, and N may be implanted on the AlGaN layer.

The method may further include forming a passivation layer on the ion-implanted layer.

The method may further include forming a Schottky electrode in the first area on the AlGaN layer, and forming an ohmic electrode in the second area on the AlGaN layer.

In the forming of the ion-implantation preventing film, the ion-implantation preventing film may be formed in an area, excluding a third area, on the AlGaN layer. In the removing of the ion-implantation preventing film, the ion-implantation preventing film may be removed to expose the AlGaN layer through the third area.

The method may further include forming a source electrode in the first area on the AlGaN layer, forming a gate insulating layer in the second area on the AlGaN layer and forming a gate electrode on the gate insulating layer, and forming a drain electrode in the third area on the AlGaN layer.

Still another aspect of the present inventive concept encompasses a method of manufacturing a nitride based heterojunction semiconductor device. The method includes forming a gallium nitride (GaN) layer, an aluminum (Al)-doped GaN layer, and an AlGaN layer on a substrate, sequentially. An ion-implanted layer is formed by selectively implanting an ion on the AlGaN layer except a first area and a second area separate from the first area, to expose the AlGaN layer through the first area and the second area.

In the course of forming of the ion-implanted layer, an ion-implantation preventing film may be formed in the first area and the second area on the AlGaN layer. The ion-implanted layer may be formed by implanting the ion on the AlGaN layer. The ion-implantation preventing film may be removed to expose the AlGaN layer through the first area and the second area.

### BRIEF DESCRIPTION OF THE DRAWINGS

The foregoing and other features of the inventive concept will be apparent from more particular description of embodiments of the present inventive concept, as illustrated in the accompanying drawings in which like reference characters may refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIG. 1 is a cross-sectional view illustrating a structure of a nitride based heteroj unction semiconductor device according to an embodiment of the present inventive concept.

FIG. 2 is a cross-sectional view illustrating a structure of a nitride based heterojunction semiconductor device according to another embodiment of the present inventive concept.

FIGS. 3 through 8 are cross-sectional views illustrating a method of manufacturing a nitride based heterojunction semiconductor device according to an embodiment of the present inventive concept.

### DETAILED DESCRIPTION

Examples of the present inventive concept will be described below in more detail with reference to the accompanying drawings. The examples of the present inventive concept may, however, be embodied in different forms and should not be construed as limited to the examples set forth herein. Like reference numerals may refer to like elements throughout the specification.

When it is determined that a detailed description is related to a related known function or configuration which may make the purpose of the present inventive concept unnecessarily ambiguous in the description of the present inventive concept, such detailed description will be omitted. Also, terminologies used herein are defined to appropriately describe the exemplary embodiments of the present inventive concept and thus may be changed depending on a user, the intent of an operator, or a custom. Accordingly, the terminologies must be defined based on the following overall description of this specification.

In the description of embodiments of the present inventive concept, it will be understood that when a layer is referred to as being “on” another layer or substrate, it can be directly on the other layer or substrate, or intervening layers may also be present.

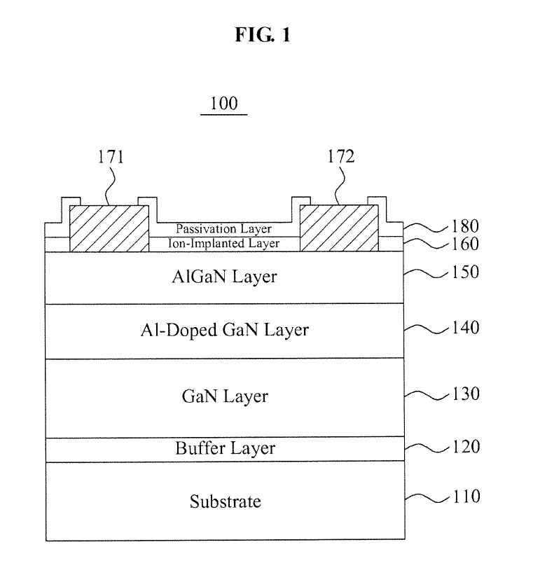

FIG. 1 is a cross-sectional view illustrating a structure of a nitride based heterojunction semiconductor device 100 according to an embodiment of the present inventive concept. The semiconductor device 100 may be a nitride based heterojunction Schottky diode, including a substrate 110, a buffer layer 120, a gallium nitride (GaN) layer 130, an aluminum (Al)-doped GaN layer 140, an AlGaN layer 150, an ion-implanted layer 160, a Schottky electrode 171, an ohmic electrode 172, and a passivation layer 180.

The buffer layer 120 may be formed on the substrate 110. Although the substrate 110 may be a sapphire substrate, it is not limited thereto. Here, the substrate 110 may be a substrate for growing nitride, for example, a silicon carbide (SiC) substrate, a nitride substrate, and the like. The buffer layer 120 may be an AlN or GaN based nitride layer, grown at a low temperature.

The GaN layer 130 may be formed on the buffer layer 120. The GaN layer 130 may be a semi-insulating GaN layer or a high resistance GaN layer. The GaN layer 130 may be grown at a low temperature, and may be grown at a high temperature. In this instance, the low temperature growth and the high temperature growth may be performed successively. For example, the GaN layer 130 may be primarily grown at a temperature ranging from 800° C. to 950° C. to secure a high resistance, and then may be secondarily grown at a temperature increased to a range of 1000° C. to 1100° C. at which a single crystal may be grown.

The Al-doped GaN layer 140 may be formed on the GaN layer 130. The Al-doped GaN layer 140 may improve crystallizability, and may improve an electrical property of a semiconductor device. That is, the Al-doped GaN layer 140 may passivate a gallium (Ga) vacancy that exists as a defect, using doped Al, thereby restraining a growth to a two-dimensional or three dimensional dislocation. Thus, the Al-doped GaN layer 140 may have excellent crystallizability. Accordingly, the Al-doped GaN layer 140 may keep the GaN layer 130, that is, the semi-insulating GaN layer or the high resistance GaN layer, from having low crystallizability. This may accomplish excellent crystal growth. Here, a content of Al to be doped may not exceed 1%. In order to sufficiently improve crystallizability, a desirable content of Al to be doped may be in the range of 0.1% to 1%, a more desirable content of Al to be doped may be in the range of 0.3% to 0.6%, and the most desirable content of Al to be doped may be about 0.45%.

The Al-doped GaN layer 140 may have a thickness in the range of 0.1 to 1 micrometer (μm). When the Al-doped GaN layer 140 has a thickness less than 0.1 μm, sufficient growth is unlikely, and the effect of crystallizability improvement may not be achieved. When the Al-doped GaN layer 140 has a thickness greater than 1 μm, an increase in a size of an element may occur when the effect of crystallizability improvement may become almost saturated.

The AlGaN layer 150 may be formed on the Al-doped GaN layer 140. A two-dimensional electron gas (2-DEG) channel (not separately shown) may be formed on an interface of the AlGaN layer 150 and the Al-doped GaN layer 140, due to discontinuity of a conduction band.

The ion-implanted layer 160 may be formed on an area of the AlGaN layer 150, excluding a first area and a second area. The first area and the second area are separate from each other. A portion of the ion-implanted layer 160 may be disposed between the first area and the second area. The first area and the second area may correspond to areas in which the Schottky electrode 171 and the ohmic electrode 172 are formed, respectively.

The ion-implanted layer 160 may be formed on the AlGaN layer 150 by implanting at least one ion of argon (Ar), carbon (C), hydrogen (H), and nitrogen (N).

When an ion is not implanted on a surface of the AlGaN layer 150, a surface state of the AlGaN layer 150 may be unstable. In particular, the AlGaN layer 150 may react with oxygen in the atmosphere so that an oxygen atom may be included in the surface of the AlGaN layer 150, or a nitrogen (N) vacancy may occur on the surface of the AlGaN layer in a chemical process, for example, dry etching, or a plasma process. The oxygen atom or the N vacancy may act as a mobile charge, and may allow a current flow on the surface of AlGaN layer 150, whereby a leakage current may occur.

According to an embodiment of the present inventive concept, when the ion-implanted layer 160 is formed by implanting ions on the surface of the AlGaN layer 150, the ions included in the ion-implanted layer 160 may offset the oxygen atom or the N vacancy included in the surface of the AlGaN layer 150. Accordingly, the oxygen atom or the N vacancy acting as a mobile charge on the surface of the AlGaN layer 150 may be reduced, thereby reducing the leakage current.

The Schottky electrode 171 may be formed in the first area on the AlGaN layer 150, and the ohmic electrode 172 may be formed in the second area on the AlGaN layer 150.

The passivation layer 180 may be formed on the ion-implanted layer 160 to expose the Schottky electrode 171 and the ohmic electrode 172. The passivation layer 180 may be formed of an insulating material, for example, aluminum oxide (Al₂O₃), silicon nitride (SiNₓ), silicon oxide (SiOₓ), and the like.

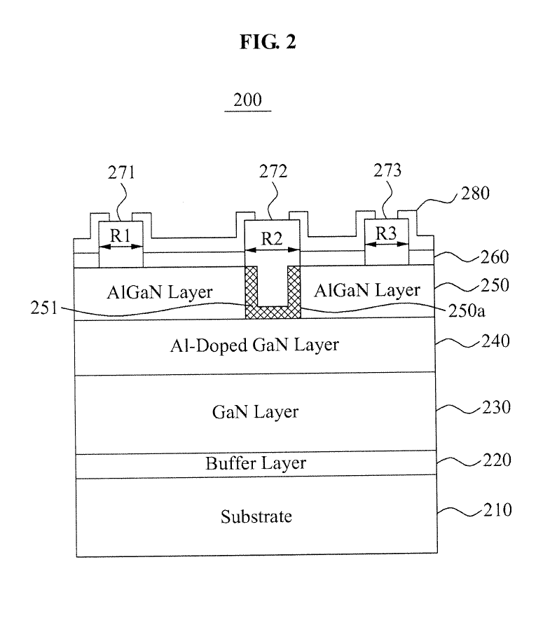

FIG. 2 is a cross-sectional view illustrating a structure of a nitride based heterojunction semiconductor device 200 according to another embodiment of the present inventive concept. The semiconductor device 200 may be a normally-OFF type nitride based heterojunction field effect transistor, including a substrate 210, a buffer layer 220, a GaN layer 230, an Al-doped GaN layer 240, an AlGaN layer 250, an ion-implanted layer 260, a gate insulating layer 251, a source electrode 271, a gate electrode 272, a drain electrode 273, and a passivation layer 280.

Since the substrate 210, the buffer layer 220, the GaN layer 230, and the Al-doped GaN layer 240 of FIG. 2 are structurally identical to the substrate 110, the buffer layer 120, the GaN layer 130, and the Al-doped GaN layer 240 of FIG. 1, duplicated descriptions will be omitted for conciseness.

The buffer layer 220 may be an AlN or GaN based nitride layer that may be grown on the substrate 210 at a low temperature.

The GaN layer 230 may be formed on the buffer layer 220, and may be a semi-insulating GaN layer or a high resistance GaN layer.

The Al-doped GaN layer 240 may be formed on the GaN layer 230.

The AlGaN layer 250 may be formed on the Al-doped GaN layer 240. A 2-DEG channel (not separately shown) may be formed on an interface of the AlGaN layer 250 and the Al-doped GaN layer 240, due to discontinuity of a conduction band.

The ion-implanted layer 260 may be formed on an area of the AlGaN layer 250, excluding a first area (R1), a second area (R2), and a third area (R3). The first area R1, the second area R2, and the third area R3 may correspond to areas in which the source electrode 271, the gate electrode 272, and the drain electrode 273 may be formed, respectively.

The AlGaN layer 250 may include a recess 250a in the second area R2. The gate insulating layer 251 may be formed in the recess 250a. That is, the gate insulating layer 251 may be formed between the recess 250a and the gate electrode 272.

According to a sequence of processes, ions may be implanted on the surface of the AlGaN layer 250 after forming a film to be used to prevent ions from being implanted in the first area R1, the second area R2, and the third area R3 on the AlGaN layer 250. For this process, the ion-implanted layer 260 may be formed in an area, excluding the first area R1, the second area R2, and the third area R3, on the surface of the AlGaN layer 250.

The first area R1, the second area R2, and the third area R3 may be exposed, and the recess 250a may be formed by etching a portion corresponding to the second area R2 on the AlGaN layer 250. The gate insulating layer 251 may be formed in the recess 250a, and the gate electrode 272 may be formed in an upper portion of the gate insulating layer 251.

The ion-implanted layer 260 may be formed by implanting at least one ion of Ar, C, H, and N. Ions included in the ion-implanted layer 260 may offset an oxygen atom or an N vacancy included in the surface of the AlGaN layer 250, thereby reducing a leakage current on the surface of the AlGaN layer 250.

The source electrode 271 may be formed in the first area R1 on the AlGaN layer 250, and the gate electrode 272 may be formed in the second area R2 on the AlGaN layer 250. Also, the drain electrode 273 may be formed in the third area R3 on the AlGaN layer 250.

The passivation layer 280 may be formed on the ion-implanted layer 260 to expose the source electrode 271, the gate electrode 272, and the drain electrode 273.

Although a structure of the normally-OFF type nitride based heterojunction field effect transistor has been described with reference to FIG. 2, an ion-implanted layer may be included in the normally-ON type of nitride based heterojunction field effect transistor to reduce a leakage current occurring on a surface of an AlGaN layer.

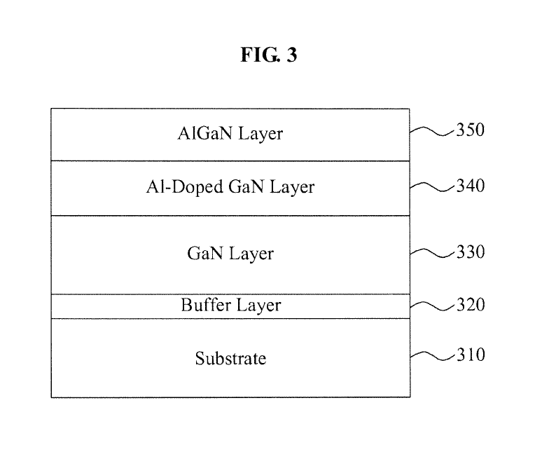

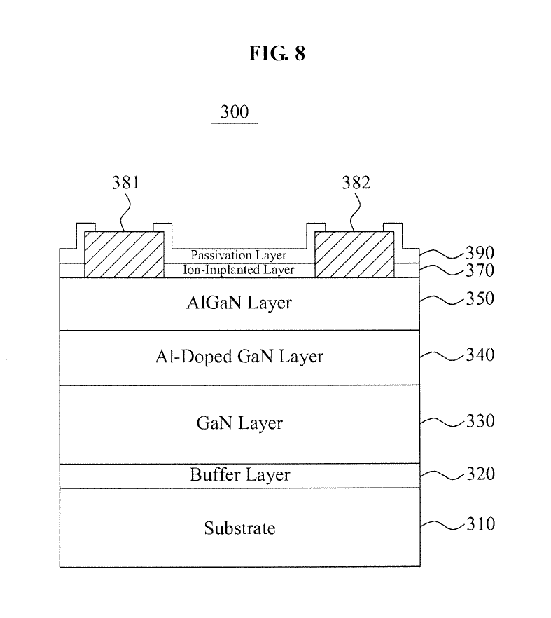

FIGS. 3 through 8 are cross-sectional views illustrating a method of manufacturing a nitride based heterojunction semiconductor device according to an embodiment of the present inventive concept. The manufacturing method illustrated in FIGS. 3 through 8 is related to a nitride based heterojunction Schottky diode 300 (see FIG. 8).

FIG. 3 illustrates a process of forming, on a substrate 310, a buffer layer 320, a GaN layer 330, an Al-doped GaN layer 340, and an AlGaN layer 350, sequentially.

The buffer layer 320 may be formed by growing, at a low temperature ranging from 500° C. to 550° C., an AlN or GaN based nitride layer on the substrate 310 used for growing nitride, for example, a sapphire substrate, a silicon carbide (SiC), a nitride substrate, or the like.

The GaN layer 330, that is, a semi-insulating GaN layer or a high resistance GaN layer, may be formed by forming, on the buffer layer 320, a Ga vacancy that may act as a deep-level trap by adjusting a grain size. In particular, the high resistance GaN layer may be formed by doping iron (Fe), C, magnesium (Mg), and zinc (Zn). During formation of the GaN layer 330 when the grain size is small, the GaN layer 330 may have a resistance value greater than 1.0×10⁹ ohms per square meter (Ω/m²) since the GaN layer 330 may include a great number of edge dislocations.

The Al-doped GaN layer 340 may be formed on the GaN layer 330. The Al-doped GaN layer 340 may improve crystallizability, and may improve an electric property of a Schottky diode. When the Al-doped GaN layer 340 is formed, a content of Al to be doped may correspond to 0.1% to 1%.

The AlGaN layer 350 may be formed on the Al-doped GaN layer 340.

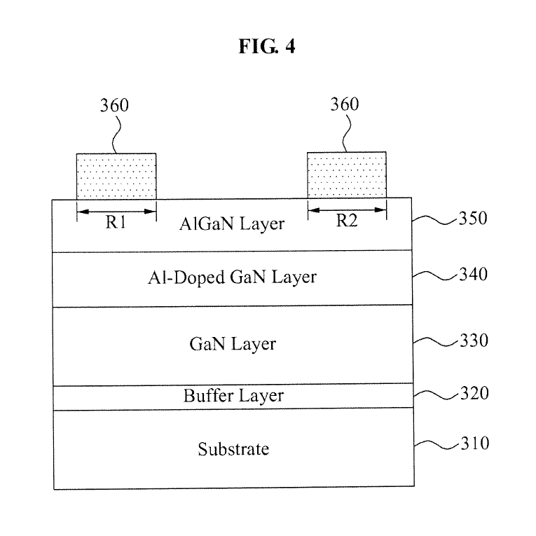

FIGS. 4-6 illustrate processes of forming an ion-implanted layer 370 by selectively implanting an ion on the AlGaN layer 350 except a first area R1, and a second area R2 separate from the first area R1, to expose the AlGaN layer 350 through the first area R1 and the second area R2. FIG. 4 illustrates a process of forming an ion-implantation preventing film 360 in the first area R1 and the second area R2 on the AlGaN layer 350. The first area R1 and the second area R2 may correspond to areas in which a Schottky electrode and an ohmic electrode may be formed, respectively. Accordingly, in order to prevent ions from being implanted in the first area R1 and the second area R2 of the AlGaN layer 350, the ion-implantation preventing film 360 may be formed by depositing a photoresist material on the first area R1 and the second area R2.

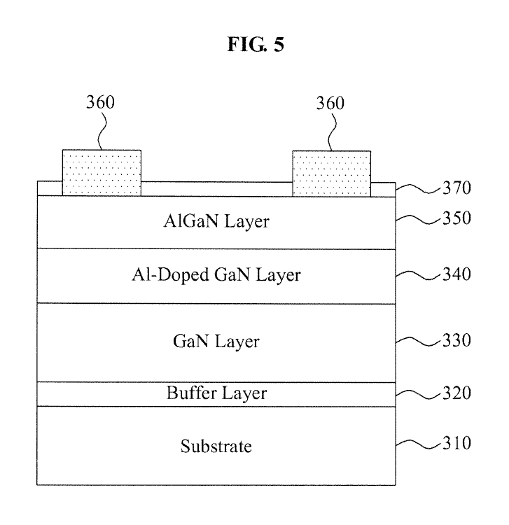

FIG. 5 illustrates a process of forming the ion-implanted layer 370 on the AlGaN layer 350. Referring to FIG. 5, the ion-implanted layer 370 may be formed on the surface of the AlGaN layer 350, by implanting, on the AlGaN layer 350, at least one ion of Ar, C, H, and N in an area, excluding the first area R1 and the second area R2.

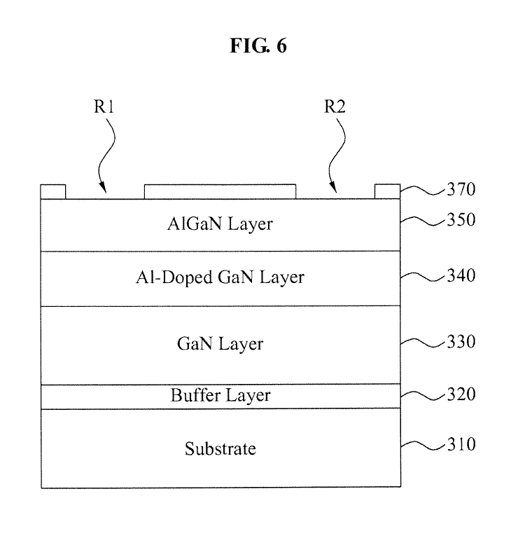

FIG. 6 illustrates a process of exposing the AlGaN layer 350 through the first area R1 and the second area R2 by removing the ion-implantation preventing film 360. The ion-implantation preventing film 360 may be removed using wet etching or dry etching.

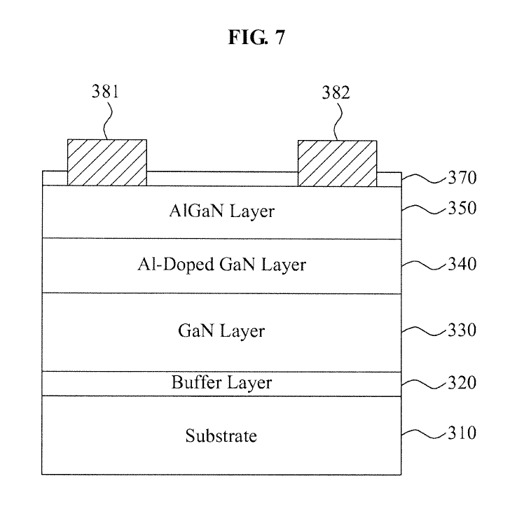

FIG. 7 illustrates a process of forming a Schottky electrode 381 in the first area R1, and forming an ohmic electrode 382 in the second area R2. Accordingly, the Schottky electrode 381 and the ohmic electrode 382 may be bonded on the AlGaN layer 350 to form a Schottky junction and an ohmic junction, respectively.

FIG. 8 illustrates a process of forming, on the ion-implanted layer 370, a passivation layer 390 that may expose the Schottky electrode 381 and the ohmic electrode 382. In particular, the passivation layer 390 may be formed by depositing an insulating material, for example, Al₂O₃, SiNₓ, SiOₓ, and the like, on the ion-implanted layer 370, the Schottky electrode 381, and the ohmic electrode 382, and etching a portion of the insulating material to expose an upper plane of the Schottky electrode 381 and an upper plane of the ohmic electrode 382.

Although the method of manufacturing the nitride based heterojunction Schottky diode 300 has been described with reference to FIGS. 3 through 8, a nitride based heterojunction field effect transistor may be manufactured by a similar method. In particular, the similar method may include a process of forming an ion-implanted layer by implanting ions on an AlGaN layer.

According to exemplary embodiments of the present inventive concept, a nitride based heterojunction semiconductor device and manufacturing method thereof may reduce a leakage current on a surface of an AlGaN layer and may increase a reliability of the device, by forming an ion-implanted layer on the surface of the AlGaN layer.

Although a few exemplary embodiments of the present inventive concept have been shown and described, the present inventive concept is not limited to the described exemplary embodiments. Instead, it would be appreciated by those skilled in the art that changes may be made to these exemplary embodiments without departing from the principles and spirit of the inventive concept, the scope of which is defined by the claims and their equivalents.

What is claimed is:

1. A nitride based heterojunction semiconductor device, comprising:
a gallium nitride (GaN) layer disposed on a substrate;
an aluminum (Al)-doped GaN layer disposed on the GaN layer;
an AlGaN layer disposed on the Al-doped GaN layer; and
an ion-implanted layer disposed on an area of the AlGaN layer, excluding a first area and a second area.

2. The semiconductor device of claim 1, wherein the ion-implanted layer includes at least one ion selected from the group consisting of argon (Ar), carbon (C), hydrogen (H), and nitrogen (N).

3. The semiconductor device of claim 1, further comprising:
a passivation layer disposed on the ion-implanted layer.

4. The semiconductor device of claim 1, further comprising:
a Schottky electrode disposed in the first area; and
an ohmic electrode disposed in the second area.

5. The semiconductor device of claim 1, wherein the ion-implanted layer is disposed in an area on the AlGaN layer, excluding a third area that is separate from the first and second areas.

6. The semiconductor device of claim 5, further comprising:
a source electrode disposed in the first area;
a gate insulating layer disposed in the second area;
a gate electrode disposed on the gate insulating layer; and
a drain electrode disposed in the third area.

7. The semiconductor device of claim 6, wherein the AlGaN layer has an etched area in which the Al-doped GaN layer is exposed through the second area.

8. The semiconductor device of claim 7, wherein the gate insulating layer is disposed between the etched area and the gate electrode.

9. A method of manufacturing a nitride based heterojunction semiconductor device, the method comprising steps of:
forming a gallium nitride (GaN) layer, an aluminum (Al)-doped GaN layer, and an AlGaN layer on a substrate, sequentially;
forming an ion-implantation preventing film in a first area and a second area on the AlGaN layer such that the first area and the second area are separate from each other;
forming an ion-implanted layer by implanting an ion on the AlGaN layer; and
removing the ion-implantation preventing film to expose the AlGaN layer through the first area and the second area.

10. The method of claim 9, wherein the step of forming an ion-implanted layer comprises the step of:
implanting, on the AlGaN layer, at least one ion selected from the group consisting of argon (Ar), carbon (C), hydrogen (H), and nitrogen (N).

11. The method of claim 9, further comprising the step of:
forming a passivation layer on the ion-implanted layer.

12. The method of claim 9, further comprising the steps of:
forming a Schottky electrode in the first area on the AlGaN layer; and
forming an ohmic electrode in the second area on the AlGaN layer.

13. The method of claim 9, wherein
the step of forming an ion-implantation preventing film comprises the step of: forming the ion-implantation preventing film in an area, excluding a third area, on the AlGaN layer, and
the step of removing an ion-implantation preventing film comprises the step of: removing the ion-implantation preventing film to expose the AlGaN layer through the third area.

14. The method of claim 13, further comprising the steps of:
forming a source electrode in the first area on the AlGaN layer;
forming a gate insulating layer in the second area on the AlGaN layer and forming a gate electrode on the gate insulating layer; and
forming a drain electrode in the third area on the AlGaN layer.

15. A method of manufacturing a nitride based heterojunction semiconductor device, the method comprising steps of:
forming a gallium nitride (GaN) layer, an aluminum (Al)-doped GaN layer, and an AlGaN layer on a substrate, sequentially; and
forming an ion-implanted layer by selectively implanting an ion on the AlGaN layer except a first area and a second area separate from the first area, to expose the AlGaN layer through the first area and the second area.

16. The method of claim 15, wherein the step of forming an ion-implanted layer comprises the steps of:
forming an ion-implantation preventing film in the first area and the second area on the AlGaN layer;
forming the ion-implanted layer by implanting the ion on the AlGaN layer; and
removing the ion-implantation preventing film to expose the AlGaN layer through the first area and the second area.

17. The semiconductor device of claim 1, wherein a portion of the ion-implanted layer is disposed between the first area and the second area on the AlGaN layer.
